(19) United States
(12) Patent Application Publication
(10) Pub. No.: US 2023/0005758 A1
(43) Pub. Date: Jan. 5, 2023

(54) PACKAGED CHIP AND MANUFACTURING METHOD THEREOF, REWIRED PACKAGED CHIP AND MANUFACTURING METHOD THEREOF

(71) Applicant: SHENNAN CIRCUITS CO., LTD., Shenzhen (CN)

(72) Inventor: Lixiang HUANG, Shenzhen (CN)

(21) Appl. No.: 17/391,058

(22) Filed: Aug. 2, 2021

Related U.S. Application Data
(63) Continuation of application No. PCT/CN2021/103813, filed on Jun. 30, 2021.

(51) Int. Cl. H01L 21/56; H01L 23/00; H01L 23/31

(52) U.S. Cl. CPC H01L 21/56; H01L 24/19; H01L 24/20; H01L 23/3135; H01L 2224/2101

(57) ABSTRACT

The present application provides a method for manufacturing a packaged chip and a packaged chip, a method for manufacturing a rewired packaged chip and a rewired packaged chip. In the present application, a dielectric layer that covers the surface of the chip and the conductive surface of the pads does not need to be partially removed by etching, the airtightness of the package chip may be improved to avoid the oxidation of the pads by air contact, and the pads are avoided from being etched by an etching process, such that the surface of the chip may be protected from being corroded by etching solution, which may result in short circuit.

### CROSS REFERENCE TO RELATED APPLICATIONS

The present application is a continuation-application of International (PCT) Patent Application No. PCT/CN2021/103813 filed on Jun. 30, 2021, and the entire contents of which are hereby incorporated by reference in their entireties.

### TECHNICAL FIELD

The present disclosure relates to the field of circuit boards, and in particular to a method of manufacturing a packaged chip and a packaged chip, a method of manufacturing a rewired packaged chip and a rewired packaged chip.

### BACKGROUND

In the art, after a packaged chip are manufactured, a pad on a surface of the chip may be exposed to air and may be easily oxidized by the air to form a layer of oxide, or an oxide layer may directly be formed on the pad for protection. As the packaged chip is sold to a downstream vendor, the downstream vendor may etch the oxide layer to expose a conductive surface of the pad, and then perform other processes.

### SUMMARY OF THE DISCLOSURE

The present disclosure provides a method of manufacturing a packaged chip and a packaged chip, a method of manufacturing a rewired packaged chip and a rewired packaged chip, which may solve the problem that etching the oxide layer of a packaged chip may easily lead to formation of a channel on a surface of the chip between adjacent pads and further lead to a short circuit of the adjacent pads.

According to a first aspect of the present disclosure, a method for manufacturing a packaged chip includes: providing a chip; and providing a dielectric layer to cover a side surface of the chip on which a plurality of pads are disposed, wherein a conductive surface of the plurality of pads contacts the dielectric layer.

In some embodiments, the providing a dielectric layer to cover a side surface of the chip on which a plurality of pads are disposed, includes: providing polyimide or photoresist to cover the side surface of the chip on which the plurality of pads are disposed, such that the polyimide or the photoresist contacts a surface of the chip and the conductive surface of the plurality of pads; and providing resin to wrap the chip and the polyimide or the photoresist.

According to a second aspect of the present disclosure, a method for manufacturing a rewired packaged chip includes: providing a packaged chip, wherein the packaged chip comprises a chip and a dielectric layer, and the dielectric layer covers a side surface of the chip on which a plurality of pads are disposed; defining a through hole in the dielectric layer at a position corresponding to each of the plurality of pads; and performing an electroplating process on the chip that defines the through hole, and a conductive post being formed in the through hole.

In some embodiments, the dielectric layer includes a first dielectric layer that contacts a conductive surface of the pad and a second dielectric layer that wraps the chip and the first dielectric layer. The defining a through hole in the dielectric layer at a position corresponding to each of the plurality of pads, includes: defining the through hole in the first dielectric layer and the second dielectric layer at the position corresponding to each of the plurality of pads; and performing the electroplating process on the chip that defines the through hole, and the conductive post being formed in the through hole.

In some embodiments, a heating process or a UV curing process is performed to cure the polyimide or the photoresist to form the first dielectric layer, the second dielectric layer is formed by curing resin. The defining the through hole in the first dielectric layer and the second dielectric layer at the position corresponding to each of the plurality of pads, includes: performing a laser drilling process to remove the resin of the second dielectric layer at the position corresponding to the pad; and performing a plasma process or a UV laser process to remove the polyimide or the photoresist of the first dielectric layer at the position corresponding to the pad, such that the through hole being defined.

In some embodiments, the defining a through hole in the dielectric layer at a position corresponding to each of the plurality of pads, includes: performing a laser drilling process on the dielectric layer at the position corresponding to the pad.

According to a third aspect of the present disclosure, a packaged chip includes: a chip; a plurality of pads, disposed on a surface of the chip; a dielectric layer, covering the surface of the chip on which the plurality of pads are disposed and covering the plurality of pads.

In some embodiments, a conductive layer of each of the plurality of pads contacts the dielectric layer; and/or the number of dielectric layers is more than one, the dielectric layer comprises a first dielectric layer and a second dielectric layer, the first dielectric layer is disposed between the second dielectric layer and the surface of the chip; and/or the first dielectric layer comprises polyimide or photoresist, and the second dielectric layer comprises resin.

According to a fourth aspect of the present disclosure, a rewired packaged chip is provided, and the packaged chip includes: a chip; a plurality of pads, disposed on a surface of the chip; a dielectric layer, covering the surface of the chip on which the plurality of pads are disposed and defining a through hole at a position corresponding to each of the plurality of pads, wherein a wall of the through hole has an axially flat surface; and a conductive post, received in the through hole, wherein one end of the conductive post is connected to each of the plurality of pads, and the other end of the conductive post is exposed on the dielectric layer.

In some embodiments, a conductive surface of each of the plurality of pads contacts the dielectric layer; and/or the number of dielectric layers is more than one, the dielectric layer comprises a first dielectric layer and a second dielectric layer, the first dielectric layer is disposed between the second dielectric layer and the surface of the chip; and/or the first dielectric layer comprises polyimide or photoresist, and the second dielectric layer comprises resin; and/or the through hole is a laser burnt hole or a plasma bombarded hole.

The present disclosure provides a method of manufacturing a packaged chip and a packaged chip, a method of manufacturing a rewired packaged chip and a rewired packaged chip. In the present disclosure, a dielectric layer may be disposed to cover a side surface of the chip on which the pad is disposed, and the conductive surface of the pad may contact the dielectric layer. In this way, airtightness is provided for the packaged chip to avoid oxidation of the pad by air contact. At the same time, it may avoid formation of channels while removing the oxide layer by micro-etching, which may lead to a short circuit caused by corrosion of the pad by flux.

### BRIEF DESCRIPTION OF THE DRAWINGS

In order to illustrate technical solutions of embodiments of the present disclosure more clearly, accompanying drawings used in the description of the embodiments will be described in brief. Obviously, the drawings in the following description are only some of the embodiments of the present disclosure, and for a person of ordinary skill in the art, other drawings can be obtained based on these drawings without any creative work.

FIG. 1 is a schematic view of a packaged chip in the art.

FIG. 2 is a flow chart of a method of manufacturing a packaged chip according to an embodiment of the present disclosure.

FIG. 3 is a flow chart of a method of manufacturing a rewired packaged chip according to an embodiment of the present disclosure.

FIG. 4 is a schematic view of a packaged chip according to an embodiment of the present disclosure.

FIG. 5 is a schematic view of a rewired packaged chip according to an embodiment of the present disclosure.

### DETAILED DESCRIPTION

The present disclosure is described in further detail below in conjunction with the accompanying drawings and embodiments. It is particularly noted that the following embodiments are used only to illustrate the present disclosure, but do not limit the scope of the present disclosure. Similarly, the following embodiments are only some, but not all, of the embodiments of the present disclosure, and all other embodiments obtained by a person of ordinary skill in the art without creative work shall fall within the scope of protection of the present disclosure.

An orientation or a position relationship indicated by terms “inside” and “outside” in the specification, claims, and the above-mentioned drawings of the present disclosure refer to an orientation or a position relationship shown in the drawings, or an orientation or a position relationship in which the product is customarily placed for use. The terms are used only for describing the present disclosure and for providing concise description, and are not intended to indicate or imply that the device or components referred to must be placed in a particular orientation, or constructed and operated in a particular orientation. Therefore, the terms should not be interpreted as limiting the present disclosure.

In addition, terms “first”, “second”, “third”, “fourth”, and the like (if present) in the specification, claims, and the accompanying drawings of the present disclosure are used to distinguish similar objects, and may not be used to describe a particular order or sequence. It should be understood that features used in this way are interchangeable when appropriate, such that embodiments of the present disclosure may be implemented in an order other than the order illustrated or described herein. In addition, terms “including”, “having”, and any variations thereof, are intended to cover non-exclusive inclusion.

As shown in FIG. 1, FIG. 1 is a schematic view of a packaged chip in the art. The packaged chip 10 in the art may include a chip 101, a plurality of pads 102, photoresist 103 and encapsulation resin 104. The plurality of pads 102 may be disposed on a side surface of the chip 101. An oxidation layer is configured on a surface of each of the plurality of pads. In addition, the photoresist 103 may cover the side surface of the chip 101 on which the pads 102 are disposed, and a part of the oxidation layer on a surface of the pad may be exposed. The encapsulating resin 104 may wrap surfaces of the chip 101 other than the surface on which the plurality of pads 102 are disposed. In order to facilitate subsequent manufacturing processes, the oxidation layer on the surface of the pad 102 needs to be removed. In detail, acidic or alkaline solution may be applied for cleaning the surface. While cleaning, the acidic or alkaline solution may corrode the oxidation layer on the surface of the pad and the surface of the chip. In this way, a channel with certain depth (not shown) may be formed between adjacent pads 102, and some of the solution may remain in the channel. The solution in the channel may enable the adjacent pads 102 to be conductive, resulting in a short circuit between the adjacent pads 102, and leading to a problem of the packaged chip 10 being unable to work properly.

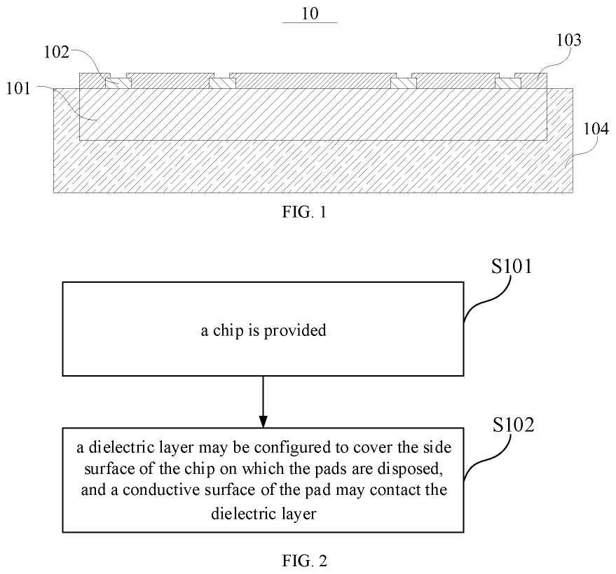

FIG. 2 is a flow chart of a method of manufacturing a packaged chip according to an embodiment of the present disclosure.

In an operation S101, a chip is provided.

In the present embodiment, a plurality of pads may be formed on a side surface of the chip. Each of the plurality of pads may have a conductive surface. The chip may be conductive to an external component through the pads, such as through the conductive surface of each pad. The pads may be made of nickel, copper, titanium, or formed by a stack a plurality of layers of nickel, copper, titanium. For example, the pads may be Al/Cu pads or Ti/Cu pads. In detail, each of the plurality of pads may include a titanium layer and a copper layer disposed above the titanium layer. Alternatively, each of the plurality of pads may include an aluminum layer and a copper layer disposed above the aluminum layer.

In an operation S102, a dielectric layer may be configured to cover the side surface of the chip on which the pads are disposed, and the conductive surface of the pad may contact the dielectric layer.

In the present embodiment, after the plurality of pads are formed on the side surface of the chip, further, the dielectric layer may be configured to cover the side surface of the chip on which the plurality of pads are disposed. The conductive surface of the pad may contact the dielectric layer. By configuring the dielectric layer to cover the side surface of the chip on which the plurality of pads are disposed, airtightness of the chip may be improved. At the same time, the dielectric layer covers the plurality of pads, such that surfaces of the pads may be prevented from being exposed to the air to be oxidized to form an oxidation layer.

In an embodiment, the dielectric layer may be polyimide or photoresist. The polyimide or photoresist may be configured to cover the side surface of the chip on which the plurality of pads are disposed, such that the polyimide or the photoresist may contact the side surface of the chip and the conductive surface of the pad. The dielectric layer may cover the entire exposed surfaces of the pads so that the surfaces of the pads may not contact the air. In detail, the polyimide or the photoresist may be provided in a fluid form and coated to the side surface of the chip on which the plurality of pads are disposed. Further, a heating process or an ultraviolet (UV) curing process may be performed to cure the polyimide or the photoresist, such that the polyimide or the photoresist may cover the side surface of the chip on which the plurality of pads are disposed.

Alternatively, after the dielectric layer covers the side surface of the chip on which the pads are disposed, the chip may further be packaged. In detail, resin may be configured to wrap the chip and the polyimide or the photoresist. Packaging by resin may protect a chip circuit from being corroded by impurities in the air, which may result in decreasing in the electrical performance of the chip. Further, an appearance of the chip, articulated leads, and the like, may be maintained.

In another embodiment, the dielectric layer may be resin. The resin may cover the side surface of the chip on which the plurality of pads are disposed, such that the resin may contact the side surface of the chip and the conductive surface of the pad. In detail, the resin may be coated on the side surface of the chip on which the pads are disposed, and the resin may be heated and cured to form the dielectric layer. In this way, the resin may cover the side surface of the chip on which the pads are disposed, which may prevent the oxidation layer on the surfaces of the pads and the surface of the chip from being corroded by the solution, and the chip may be packaged.

According to the present disclosure, the dielectric layer may cover the side surface of the chip on which the pads are disposed, and the conductive surface of the pad may contact the dielectric layer. The dielectric layer covering the side surface of the chip and the conductive surface of the pad does not need to be partially removed by etching. Therefore, while improving the airtightness of the package chip to avoid the pad from being oxidized by air contact, the etching process performed on the pad may be avoided, such that the surface of the chip may be avoided from being corroded by the etching solution, which may lead to the short circuit.

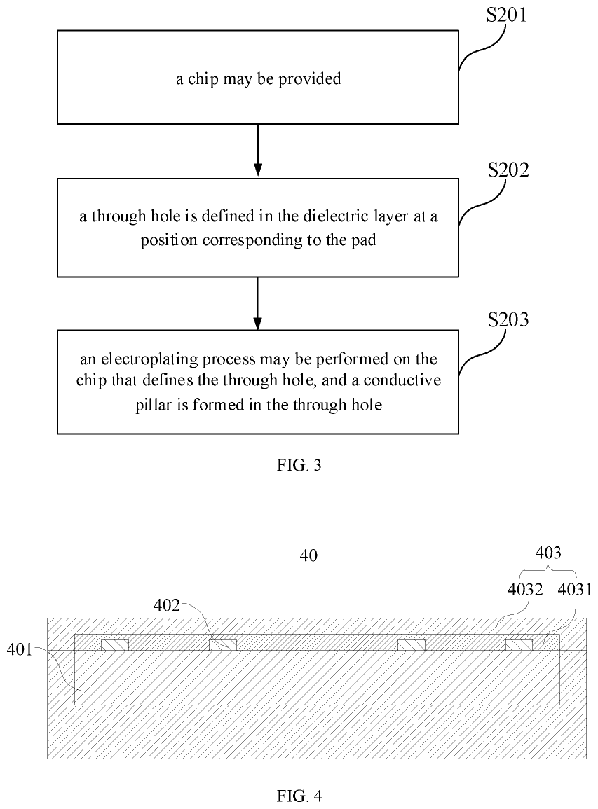

FIG. 3 is a flow chart of a method of manufacturing a rewired packaged chip according to an embodiment of the present disclosure.

In an operation S201, a chip may be provided.

After the packaged chip from an upstream manufacturer is passed to the downstream vendor, a further process may need to be performed. In the present embodiment, the downstream vendor may get ready with the packaged chip that is to be processed, and the packaged chip may include the chip and the dielectric layer covering the side surface of the chip on which the plurality of pads are disposed, and the conductive surface of the pad may contact the dielectric layer.

In an embodiment, the dielectric layer may include a first dielectric layer that contacts the surface of the pad and a second dielectric layer that wraps the chip and the first dielectric layer. The first dielectric layer may be formed by performing the heat process or the UV curing process on the polyimide or the photoresist. The second dielectric layer may be formed by curing the resin. Alternatively, before curing the resin, cleaning by acidic or alkaline solution may be performed to remove surface impurities, preventing the impurities from affecting chip performance. As the first dielectric layer may contact the side surface of chip and the conductive surface of the pad, the airtightness of the chip may be improved, and the chip may be prevented from being damaged by the etching solution. At the same time, the first dielectric layer may prevent the surface of the pad from being exposed to the air to be oxidized to form an oxidation layer. The second dielectric layer may be configured to package the chip to protect the chip circuit from being corroded by the impurities in the air, which may result in decreasing in the electrical performance of the chip. Further, an appearance of the chip, articulated leads, and the like, may be maintained.

In an operation S202, a through hole is defined in the dielectric layer at a position corresponding to each of the plurality of pads.

In the present embodiment, the dielectric layer covers the side surface of the chip on which the pads are disposed. The packaged chip may be connected to the external components through the pads. Therefore, it may be required to define a through hole in the dielectric layer at a position corresponding to each pad, and to remove the dielectric layer on the surface of the pad. In this way, the pads may be partially exposed from the through hole to be connected to the external components.

In an embodiment, the dielectric layer may include a first dielectric layer that contacts the surfaces of the pads and a second dielectric layer that wraps the chip and the first dielectric layer. In detail, the through hole is defined in the first dielectric layer and the second dielectric layer at the position corresponding to the pad. The second dielectric layer may be formed by curing resin. Therefore, the resin of the second dielectric layer at the position corresponding to the pad may be removed by a laser drilling process. The first dielectric layer may be formed by performing the heating process on the polyimide or the photoresist or performing the UV curing process on the polyimide or the photoresist to cure the polyimide or the photoresist. Therefore, the polyimide or the photoresist of the first dielectric layer at the position corresponding to the pad may be removed by a plasma or a UV laser process, such that the through hole is defined. The through hole may be a laser burnt hole or a plasma bombarded hole, and thus unlike a solution etched hole. A wall of the through hole defined in the present disclosure may be have an axially flat surface. In the present disclosure, the position of the through hole may be determined by the laser drilling process. The through hole may further be defined precisely by the plasma or the UV laser process without damaging the pads. At the same time, the through hole may be defined at any position of the pads. In the present disclosure, an area that is allowed to define the through hole may be larger, and the through hole may be defined more accurately. It may avoid a part of the through hole being defined at a position that does not correspond to the pad, such that the yield of the packaged chip may be improved, and it is not necessary to increase the pad area to prevent the through hole from being defined non-correspondence to the pad.

In an operation S203, an electroplating process may be performed on the chip that defines the through hole, and a conductive post is formed in the through hole.

In the present embodiment, after the through hole is defined in the dielectric layer at the position corresponding to the pad, the electroplating process may be performed on the chip that defines the through hole, such that the conductive post is formed in the through hole. One end of the conductive post may be connected to the conductive surface of the pad, and the other end may be exposed from the dielectric layer. An area of a surface of the conductive post that contacts the pad may not be greater than an area of the conductive surface of the pad. A rewired process is performed through the conductive post to conduct the chip with the external component to achieve various functions.

In the present disclosure, the dielectric layer may cover the side surface of the chip on which the pads are disposed, and the conductive surface of the pad may contact the dielectric layer. The dielectric layer that covers the surface of the chip and the conductive surface of the pad does not need to be partially removed by etching. Therefore, the airtightness of the packaged chip is improved to avoid the pad from being oxidized by air contact, the pad may not be etched by the etching process, such that the surface of the chip may be avoided from being corroded by the etching solution, which may cause the short circuit.

As shown in FIG. 4, FIG. 4 is a schematic view of a packaged chip according to an embodiment of the present disclosure. The packaged chip 40 in the present disclosure may include a chip 401, a plurality of pads 402, and a dielectric layer 403.

In the present embodiment, the plurality of pads 402 are disposed on a side surface of the chip 401. The pads 402 may be formed by nickel, copper, titanium or a stack of multiple layers of nickel, copper and titanium. For example, the pads may be Al/Cu pads or Ti/Cu pads. Each of the plurality of pads 402 may include a titanium layer and a copper layer disposed above the titanium layer. Alternatively, each of the plurality of pads 402 may include an aluminum layer and a copper layer disposed above the aluminum layer.

The dielectric layer 403 may cover the side surface of the chip 401 on which the plurality of pads 402 are disposed. The dielectric layer 403 may cover the plurality of pads 402. The dielectric layer 403 may cover the entire exposed surfaces of the pads 402 so that the surfaces of the pads 402 may not contact the air.

In an embodiment, each pad 402 may have a conductive surface, and the conductive surface may contact the dielectric layer 403. The number of dielectric layers 403 may be two, including a first dielectric layer 4031 and a second dielectric layer 4032. The first dielectric layer 4031 may be disposed between the second dielectric layer 4032 and the side surface of the chip 401. The first dielectric layer 4031 may include polyimide or photoresist. The polyimide or the photoresist may be provided in a fluid form and coated on the side surface of the chip 401 on which the plurality of pads 402 are disposed. Further, a heating process or a UV curing process may be performed to cure the polyimide or the photoresist to form the first dielectric layer 4031. The second dielectric layer 4032 may include resin. The second dielectric layer 4032 may wrap the chip 401 and the first dielectric layer 4031, such that an air corrosion which may result in decreasing in the electrical performance of the chip may be avoided. Further, an appearance of the chip, articulated leads, and the like, may be maintained.

According to the present disclosure, the dielectric layer of the packaged chip may cover the side surface of the chip on which the plurality of pads are disposed. The dielectric layer may cover the plurality of pads. The dielectric layer that covers the side surface of the chip and the conductive surfaces of the pads does not need to be partially removed by etching. Therefore, the air tightness of the packaged chip may be improved to avoid the pads being oxidized by air contact, and the pads may be avoided from being etched by the etching process, such that the surface of the chip may be avoided from being corroded by the etching solution, which may cause the short circuit.

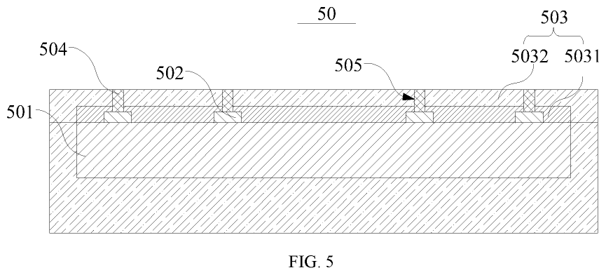

As shown in FIG. 5, FIG. 5 is a schematic view of a rewired packaged chip according to an embodiment of the present disclosure. The rewired packaged chip 50 may include a chip 501, a plurality of pads 502, a dielectric layer 503, and a conductive post 504.

In the present embodiment, the plurality of pads 502 are disposed from a side surface of the chip 501. The pads 502 may be formed by nickel, copper, titanium or a stack of multiple layers of nickel, copper, titanium. For example, the pads may be Al/Cu pads or Ti/Cu pads. Each of the plurality of pads 502 may include a titanium layer and a copper layer disposed above the titanium layer. Each of the plurality of pads 502 may include an aluminum layer and a copper layer disposed above the aluminum layer.

The dielectric layer 503 may cover the side surface of the chip 501 on which the plurality of pads 502 are disposed. The dielectric layer 503 may cover the plurality of pads 502. The dielectric layer 503 may cover the entire exposed surfaces of the pads 502, such that the exposed surfaces of the pads may not contact the air. A through hole 505 may be defined in the dielectric layer 503 at a position corresponding to the pad 501. A wall of the through hole 505 may have an axially flat surface. The through hole 505 may be a laser burned hole or a plasma bombarded hole.

In an embodiment, each pad 502 may have a conductive surface, and the conductive surface may contact the dielectric layer 503. The number of dielectric layers 503 may be two, including a first dielectric layer 5031 and a second dielectric layer 5032. The first dielectric layer 5031 may be disposed between the second dielectric layer 5032 and the surface of the chip 501. The first dielectric layer 5031 may include polyimide or photoresist. The polyimide or the photoresist may be provided in a fluid form and coated on the side surface of the chip 501 on which the plurality of pads 502 are disposed. A heating process or a UV curing process may be performed to cure the polyimide or the photoresist to form the first dielectric layer 5031. The second dielectric layer 5032 may include resin. The second dielectric layer 5032 may wrap the chip 501 and the first dielectric layer 5031, such that an air corrosion which may result in decreasing in the electrical performance of the chip may be avoided. Further, an appearance of the chip, articulated leads, and the like, may be maintained.

A laser drilling process may be performed to remove the resin of the second dielectric layer 5032 at the position corresponding to the pad, and a plasma process or a UV laser process may be performed to remove the polyimide or the photoresist of the first dielectric layer 5031 at the position corresponding to the pad, such that the through hole may be defined. The position in which the through hole 505 is defined may correspond to at any position of the conductive surface of the pad 502. In the present disclosure, an area that is allowed to define the through hole 505 may be larger, and the through hole may be defined more accurately, the through hole may be avoided from being defined in an area that does not correspond to the pad 502, such that the yield of the packaged chip may be improved. Further, it may not need to increase the area of the pad 502 to prevent the through hole 505 from being defined non-correspondence to the pad 502.

In the present embodiment, the conductive post 504 may be received in the through hole 505. One end of the conductive post 504 may be connected to the pad 502, and the other end may be exposed to the dielectric layer 503. The conductive post 504 may be a copper post, an may be formed by performing an electroplating process in the through hole 505. The conductive post 504 may be configured to conduct the chip 501 with the external components to achieve various functions. The conductive post 504 may be connected to any position of the conductive surface of the pad 502. Compared to exposing a part of the pad, an area of the pad 502 that allows the conductive post 504 to be connected may be greater, and a part of the conductive post 504 may be avoided from being configured out of the pad, improving the yield of the packaged chip.

In the present disclosure, the dielectric layer may cover the side surface of the chip on which the pads are disposed, and the dielectric layer may cover the pads. The dielectric layer that covers the side surface of the chip and the conductive surfaces of the pads does not need to be partially removed by etching. Therefore, the air tightness of the packaged chip may be improved to avoid the pads being oxidized by air contact, and the pads may be avoided from being etched by the etching process, such that the surface of the chip may be avoided from being corroded by the etching solution, which may cause the short circuit. Further, in the present disclosure, an area that is allowed to define the through hole may be larger, and the through hole may be defined more accurately. It may be avoided that a part of the through hole is defined in an area out of the pad, such that the yield of the packaged chip may be improved. It may not need to increase the area of the pad to prevent through hole from being defined out of the pad.

The above description shows only embodiments of the present disclosure, but does not limit the scope of the present disclosure. Any equivalent structure or equivalent process transformation based on the specification and the accompanying drawings of the present disclosure, applied directly or indirectly in other related arts, shall be included in the scope of the present disclosure.

What is claimed is:

1. A method for manufacturing a packaged chip, comprising:
providing a chip;
providing a dielectric layer to cover a side surface of the chip on which a plurality of pads are disposed, wherein a conductive surface of the plurality of pads contacts the dielectric layer.

2. The method according to claim 1, wherein the providing a dielectric layer to cover a side surface of the chip on which a plurality of pads are disposed, comprises:
providing polyimide or photoresist to cover the side surface of the chip on which the plurality of pads are disposed, such that the polyimide or the photoresist contacts a surface of the chip and the conductive surface of the plurality of pads; and
providing resin to wrap the chip and the polyimide or the photoresist.

3. A method for manufacturing a rewired packaged chip, comprising:
providing a packaged chip, wherein the packaged chip comprises a chip and a dielectric layer, and the dielectric layer covers a side surface of the chip on which a plurality of pads are disposed;
defining a through hole in the dielectric layer at a position corresponding to each of the plurality of pads; and
performing an electroplating process on the packaged chip that defines the through hole, and a conductive post being formed in the through hole.

4. The method according to claim 3, wherein the dielectric layer comprises a first dielectric layer that contacts a conductive surface of the pad and a second dielectric layer that wraps the chip and the first dielectric layer; and
the defining a through hole in the dielectric layer at a position corresponding to each of the plurality of pads, comprises:
defining the through hole in the first dielectric layer and the second dielectric layer at the position corresponding to each of the plurality of pads; and
performing the electroplating process on the chip that defines the through hole, and the conductive post being formed in the through hole.

5. The method according to claim 4, wherein a heating process or a UV curing process is performed to cure the polyimide or the photoresist to form the first dielectric layer, the second dielectric layer is formed by curing resin, and the defining the through hole in the first dielectric layer and the second dielectric layer at the position corresponding to each of the plurality of pads, comprises:
performing a laser drilling process to remove the resin of the second dielectric layer at the position corresponding to the pad; and
performing a plasma process or a UV laser process to remove the polyimide or the photoresist of the first dielectric layer at the position corresponding to the pad, such that the through hole being defined.

6. The method according to claim 3, wherein the defining a through hole in the dielectric layer at a position corresponding to each of the plurality of pads, comprises:
performing a laser drilling process on the dielectric layer at the position corresponding to the pad.

7. The method according to claim 3, wherein one end of the conductive post is connected to each of the plurality of pads, and the other end of the conductive post is exposed on the dielectric layer.

8. The method according to claim 3, wherein the dielectric layer covers entire surfaces of the plurality of pads.

9. A rewired packaged chip, the packaged chip comprising:
a chip;
a plurality of pads, disposed on a surface of the chip;
a dielectric layer, covering the surface of the chip on which the plurality of pads are disposed and defining a through hole at a position corresponding to each of the plurality of pads, wherein a wall of the through hole has an axially flat surface; and
a conductive post, received in the through hole, wherein one end of the conductive post is connected to each of the plurality of pads, and the other end of the conductive post is exposed from the dielectric layer.

10. The rewired packaged chip according to claim 9, wherein
a conductive surface of each of the plurality of pads contacts the dielectric layer.

11. The rewired packaged chip according to claim 9, wherein
the number of dielectric layers is more than one, the dielectric layer comprises a first dielectric layer and a second dielectric layer, the first dielectric layer is disposed between the second dielectric layer and the surface of the chip.

12. The rewired packaged chip according to claim 11, wherein the first dielectric layer is configured to cover the surface of the chip and at least a part of a surface of each of the plurality of pads, and the second dielectric layer is configured to cover the chip and the first dielectric layer.

13. The rewired packaged chip according to claim 9, wherein the first dielectric layer comprises polyimide or photoresist, and the second dielectric layer comprises resin.

14. The rewired packaged chip according to claim 9, wherein the through hole is a laser burnt hole or a plasma bombarded hole.
